(19) United States
(12) Patent Application Publication
(10) Pub. No.: US 2009/0274334 A1
(43) Pub. Date: Nov. 5, 2009

(54) Mounting Method and Holder for SMD Microphone

(76) Inventors: Chang-Won Kim, Incheon (KR); Sang-Ho Lee, Gyeonggi-do (KR)

Correspondence Address: KEUSEY, TUTUNJIAN & BITETTO, P.C., 20 CROSSWAYS PARK NORTH, SUITE 210, WOODBURY, NY, 11797, US

(21) Appl. No.: 12/085,117

(22) PCT Filed: Dec. 29, 2006
(86) PCT No.: PCT/KR2006/005866

§ 371 Date: May 16, 2008

(30) Foreign Application Priority Data
May 22, 2006 (KR) 10-2006-0045693
Jun. 20, 2006 (KR) 10-2006-0055459

(51) Int. Cl. H04R 1/02; H05K 3/30

(52) U.S. Cl. 381/368; 381/361; 29/832

(57) ABSTRACT

A SMD microphone holder has an SMD microphone mounted within, and includes a cap body and cylindrical portion. The cap body is withstands a reflow temperature, and defines a cavity for mounting the SMD microphone therein. The cylindrical portion is formed with the cap body, and withstands a reflow temperature. The cap body includes a center hole, a tool contacting surface, and a shock absorbing protrusion. The center hole, through which outside sound enters, is formed in an upper surface of the cap body. The tool contacting surface is formed around the center hole, to facilitate use of a vacuum tool during a mounting of the SMD microphone. The shock absorbing protrusion is formed on an upper, inner perimeter surface of the cap body in a radial direction about the center hole, to avert direct surface friction between the cap body and a sound hole of the SMD microphone.

### TECHNICAL FIELD

The present invention relates to a method of mounting a condenser microphone on a mainboard of an electronic device such as a mobile phone, and more particularly, to a method of mounting a surface mounted device (SMD) condenser microphone on a mainboard of an electronic device using an SMD method and a microphone holder suitable for the SMD condenser microphone.

### BACKGROUND ART

Generally, electret condenser microphones used in mobile phones and other devices are formed of a diaphragm/backplate combination which form a capacitor (C) that responds and changes according to a voltage bias element (usually composed of electrets) and sound pressure, and a junction field effect transistor (JFET) for buffering output signals. Such a condenser microphone is used in conjunction with a microphone holder, in order to produce better sound characteristics and protect the condenser microphone.

FIG. 1 is a flowchart showing the process of mounting a conventional condenser microphone on a product's mainboard. A conventional condenser microphone is first inserted in a microphone holder by a company specializing in audio, after which the unit is shipped to an electronics manufacturer to be soldered and mounted to a mainboard. Referring to steps S101-S105 in FIG. 1, after the company specializing in audio prepares a condenser microphone and microphone holder, they couple the two pieces and ship the coupled unit to a mobile phone manufacturer; then the mobile phone manufacturer attaches the microphone that is coupled to the holder on a printed circuit board (PCB) through soldering.

Products have become increasingly miniaturized due to technological advances in electronics manufacturing, which has led to the widespread use of surface mount technology (SMT) in the manufacturing of miniature devices. Especially with small electronic devices such as mobile phones and personal digital assistants (PDAs), employing SMD methods for mounting devices is necessary. Because most components in mobile phones, etc. must be mounted using SMD methods, they are developed to withstand extreme temperatures.

However, the holders for microphones have a low tolerance of temperature extremes, and are thus unable to withstand the reflow process employed in SMD methods. As such, they are mounted to mainboards through the conventional process shown in FIG. 2.

Referring to FIG. 2, a company specializing in audio that produces condenser microphones separately prepares an SMD condenser microphone and a microphone holder, which they ship to a mobile phone manufacturer in an unassembled state. In steps S201-S204, the mobile phone manufacturer first positions the SMD microphone on the mainboard and mounts the SMD microphone using an SMD reflow process, then couples the holder to the microphone, and assembles the mobile phone cover. Here, in order to pick up the microphone capsule, a pick-up cap is sometimes used, and sometimes the holder is first installed on the mobile phone cover after which the microphone is assembled.

However, when the microphone holder and the microphone are shipped separately, the electronic device manufacturer must mount the SMD microphone to the mainboard using an SMD method and then cover the microphone with the holder. This increases manufacturing time and the number of processes, thereby raising production costs. Also, because the sound characteristics of a microphone can change according to its assembly with a holder, because conventional microphones must be assembled with their holders by non-specialists at an electronics manufacturer, there are frequent cases where the proper sound characteristics of microphones are forfeited.

### SUMMARY

To solve the above problem, the present invention provides a holder (suitable for an SMD microphone) that can withstand an SMD reflow process, allowing the microphone to be mounted to a mainboard in an assembled state, and a method of mounting the SMD microphone.

According to an aspect of the present invention, there is provided an SMD (surface mounted device) microphone holder capable of having an SMD microphone mounted within, the SMD microphone holder including: a cap body formed of a high heat resistant material capable of withstanding a reflow temperature, and defining a cavity for mounting the SMD microphone therein; and an annular cylindrical portion integrally formed with the cap body and formed of a high heat resistant material capable of withstanding a reflow temperature. The cap body may include: a center hole formed in a center of an upper surface of the cap body, through which sound from outside enters; a tool contacting surface formed around the center hole, for facilitating use of a vacuum tool during a mounting of the SMD microphone; and a shock absorbing protrusion formed on an upper, inner perimeter surface of the cap body in a radial direction about the center hole, the shock absorbing protrusion for averting direct surface friction between the cap body, and a sound hole of the SMD microphone when the vacuum tool is used.

According to another aspect of the present invention, there is provided a method for mounting an SMD (surface mounted device) microphone, including: preparing an SMD condenser microphone; preparing an SMD microphone holder; coupling the SMD condenser microphone with the SMD microphone holder; positioning the coupled SMD condenser microphone and the SMD microphone holder on a mainboard of an electronic device; and performing a reflow process on the mainboard with the coupled SMD condenser microphone and the SMD microphone holder positioned thereon.

### DESCRIPTION OF DRAWINGS

FIG. 1 is a flowchart showing the process of mounting a conventional microphone on a product's mainboard.

FIG. 2 is a flowchart showing the process of mounting a conventional SMD microphone on a product's mainboard.

FIG. 3 is a top perspective view of an SMD microphone holder according to the present invention.

FIG. 4 is a bottom perspective view of an SMD microphone holder according to the present invention.

FIG. 5 is a side sectional view of an SMD microphone holder according to the present invention.

FIG. 6 is a top plan view of an SMD microphone holder according to the present invention.

FIG. 7 is a side plan view of an SMD microphone holder according to the present invention.

FIG. 8 is a bottom plan view of an SMD microphone holder according to the present invention.

FIG. 9 is an exploded perspective view of an SMD microphone holder and a microphone prior to assembly.

FIG. 10 is a perspective view of an SMD microphone holder and a microphone after assembly.

FIG. 11 is a cutaway perspective view of an SMD microphone holder and a microphone after assembly.

FIG. 12 is a flowchart showing a process of mounting an SMD microphone and holder according to the present invention.

FIG. 13 is a cutaway perspective view of an SMD microphone mounted on a mainboard according to the present invention.

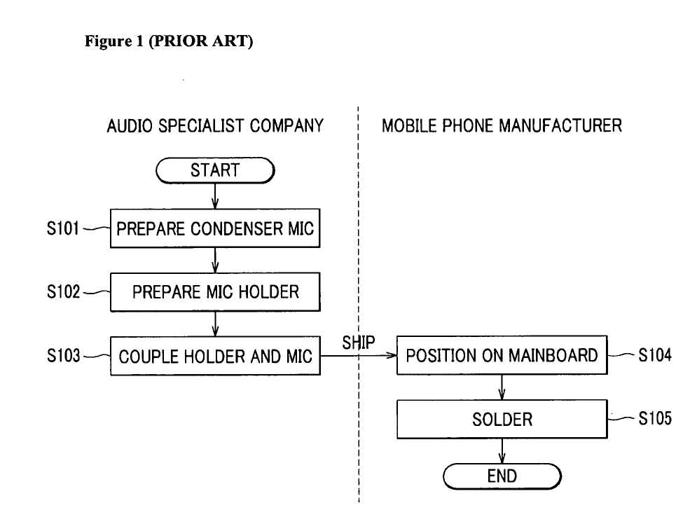

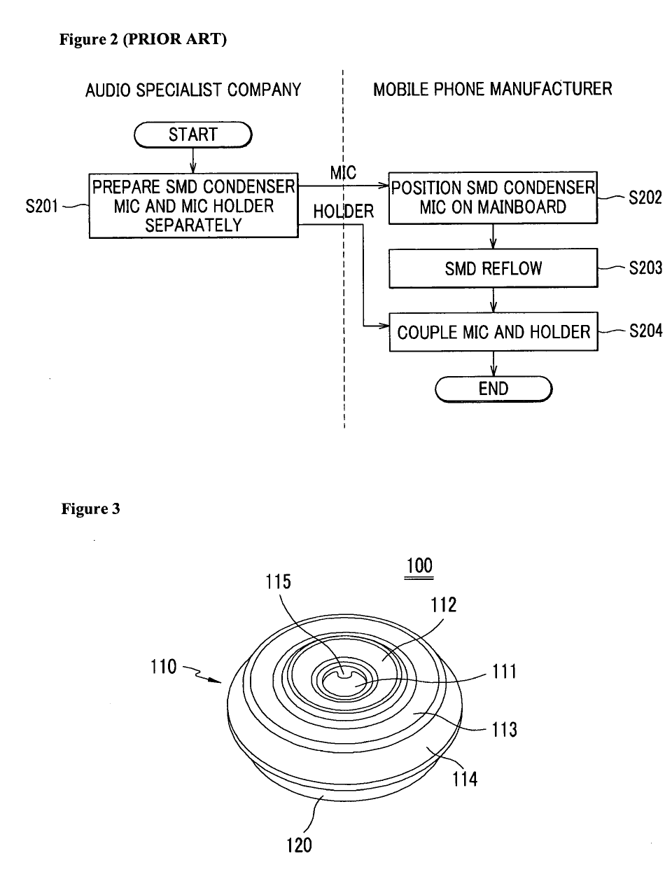

### DESCRIPTION OF THE SYMBOLS IN MAIN PORTIONS OF THE DRAWINGS

| | |
|---|---|
| 100: | holder |
| 110: | cap body |
| 111: | center hole |
| 112: | hole perimeter |
| 113: | tool contact surface |
| 114: | outer surface |
| 115: | shock absorbing protrusion |
| 120: | cylindrical portion |
| 130: | cavity |
| 200: | microphone |
| 202: | case |
| 202a: | sound hole |
| 204: | PCB |
| 204a: | contact terminal |
| 300: | main PCB |
| 310: | mobile phone cover |

### DETAILED DESCRIPTION OF PREFERRED EMBODIMENTS

Hereinafter, preferred embodiments of a method for mounting an SMD microphone and a holder for the SMD microphone according to the present invention will be described in detail with reference to the accompanying drawings.

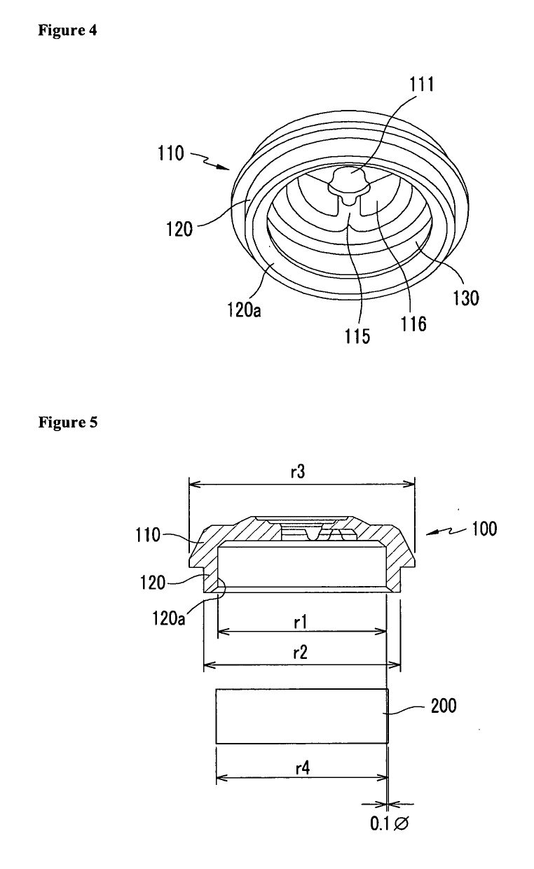

FIG. 3 is a top perspective view of an SMD microphone holder according to the present invention, and FIG. 4 is a bottom perspective view of an SMD microphone holder according to the present invention.

As shown in FIGS. 3 and 4, in order to vertically enclose a cylindrical microphone, an SMD microphone holder 100 according to the present invention includes a cap body 110 forming a cavity 130 for mounting a cylindrical microphone in, and a cylindrical portion 120 integrally formed with the cap body 110. The cap body 110 has an outer surface 114 that is inclined in a conical shape, a center hole 111 for external sound to enter through formed at the upper, central surface of the cap body 110, and a hole perimeter 112 formed to protrude upward from around the center hole 111 and having an inclined surface. A tool contact surface 113 is formed as a flat surface around the hole perimeter 112 to facilitate using a vacuum tool when mounting a microphone. Also, three shock absorbing protrusions 115 are formed to protrude on the upper, inner perimeter of the cap body at regular intervals in a radial direction toward the center hole 111, in order to avoid direct surface friction with a sound hole of a microphone (mic) when a vacuum tool is used. Thus, three shock absorbing spaces 116 are separately formed between the upper surface of the microphone and the cap body 110 by means of the three shock absorbing protrusions 115.

Referring to FIG. 5, the inner diameter r1 of the cylindrical portion 120 and the inner diameter r1 of the cap body 110 are the same, and form the cavity 130 for receiving a microphone 200. The outer diameter r2 of the cylindrical portion 120 is less than the outer diameter r3 of the cap body 110 so that the cylindrical portion 120 is stepped inward from the cap body 110. The inner diameter r1 of the cylindrical portion 120 is smaller than the outer surface of the microphone 200 to be installed therein by approximately 0.1φ to prevent the microphone 200 from disengaging after being mounted. Here, to facilitate ease of insertion when the mic is first inserted, the end portion of the cylindrical portion 120 may include a sloped surface 120a. Thus, when the microphone 200 is mounted to the holder 100 according to the present invention, the mounting of the microphone becomes easier by means of the sloped surface 120a shown in FIG. 5, and the microphone 200 does not disengage easily from the holder 100 due to its outer diameter r4 being formed slightly larger than the inner diameter r1 of the holder 100.

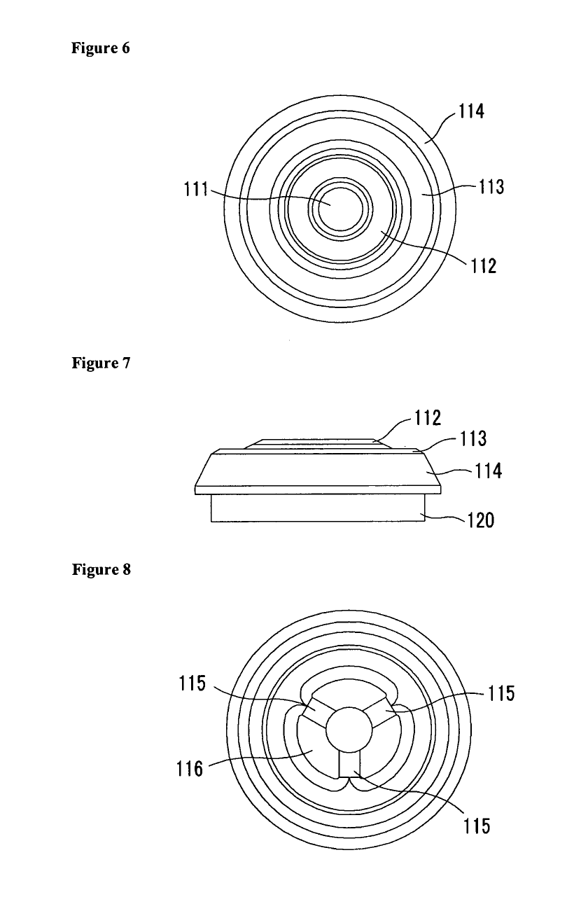

The microphone holder 100 according to the present invention: has a center hole 111 formed at the central portion, and a hole perimeter 112 and a tool contact surface 113 formed around the center hole 111, as shown in the top plan view of FIG. 6; and has the outer surface 114 of the cap body 110 protruding outward from the cylindrical portion 120 when viewed from the front or side (as shown in FIG. 7), and a hole perimeter 112 with an inclined surface at the top of the cap body. Also, the microphone holder 100 according to the present invention, when viewed from the bottom in FIG. 8, has three shock absorbing protrusions 115 formed around the center hole 111 in a radial direction to divide the perimeter around the center hole 111.

The material of the microphone holder 100 according to the present invention may be formed of a soft, yet highly heat resistant material able to withstand a reflow process. For example, a highly heat resistant silicon, rubber, or plastic may be used as a soft, yet highly heat resistant material.

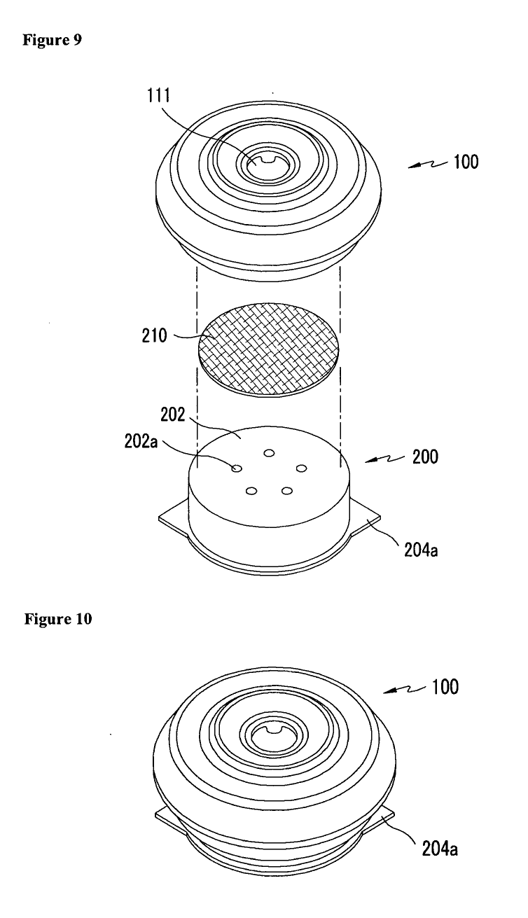

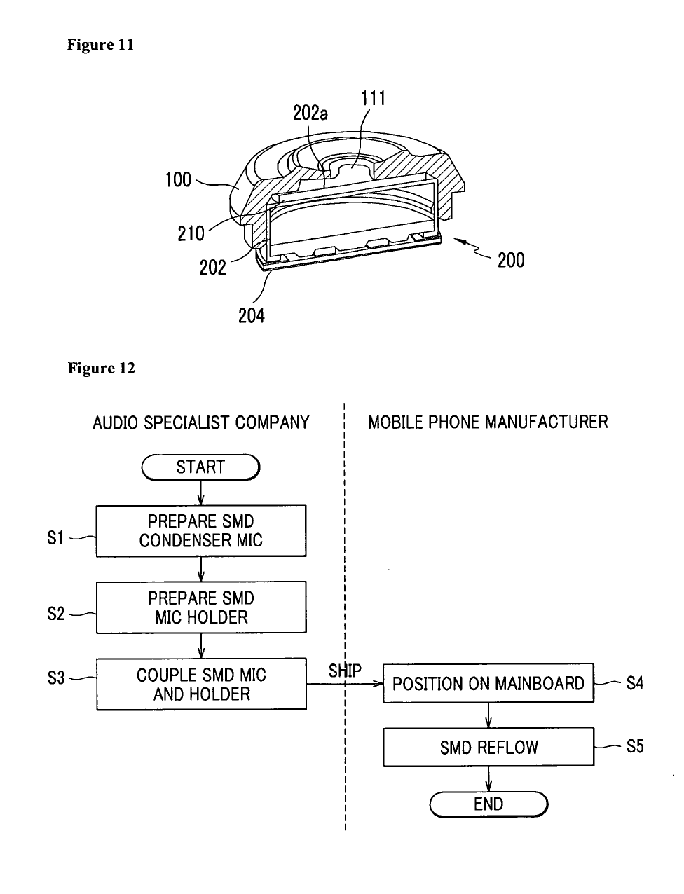

FIG. 9 is an exploded perspective view of an SMD microphone holder and a microphone prior to assembly, FIG. 10 is a perspective view of an SMD microphone holder and a microphone after assembly, and FIG. 11 is a cutaway perspective view of an SMD microphone holder and a microphone after assembly.

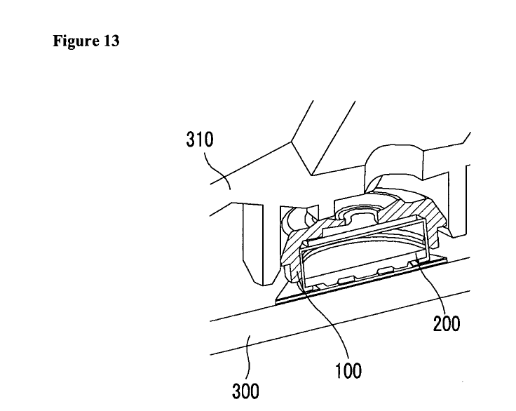

Referring to FIG. 9, a non-woven fabric 210 for preventing external dust infiltration is placed on top of the microphone 200 that includes a case 202 defining sound holes 202a and a printed circuit board (PCB) 204 with contact terminals 204a of a mainboard 300 (in FIG. 13), and the holder 100 according to the present invention covers the microphone to form a coupled unit. Thus, as shown in FIG. 10, with the holder 100 according to the present invention and the microphone 200 coupled, a vacuum tool (not shown) contacts and suctions the tool contacting surface 113 of the holder to mount the unit on a mainboard in an assembly line, whereupon soldering is performed through a reflow process.

In the microphone holder 100 according to the present invention, as shown in FIG. 11, because the sound holes 202a of the SMD microphone 200 and the center hole 111 of the SMD microphone holder 100 are designed not to align, damage to the diaphragm of the microphone 200 during the suctioning by the vacuum tool can be prevented.

FIG. 12 is a flowchart showing a process of mounting an SMD microphone and holder according to the present invention, and FIG. 13 is a cutaway perspective view of an SMD microphone mounted on a mainboard according to the present invention. As shown in FIG. 12, a process of mounting an SMD microphone 200 according to the present invention on a mainboard 300 of an electronic device, such as a mobile phone, includes the following steps. In step S1, an SMD condenser microphone 200 is prepared, in step S2, an SMD microphone holder 100 is prepared, in step S3, the SMD microphone 200 and the SMD microphone holder 100 are coupled, in step S4, the SMD microphone and the SMD microphone holder 100 are positioned in a coupled state on the mainboard 300 of an electronic device, and in step S5, a reflow process is performed on the mainboard with the SMD microphone 200 and the SMD microphone holder 100 in a coupled state.

Referring to FIG. 12, in steps S1-S5, the manufacturer of the microphone 200 prepares and couples the SMD condenser microphone 200 and the SMD microphone holder 100, after which the microphone manufacturer ships the unit to a mobile phone manufacturer; and the mobile phone manufacturer positions the microphone 200 coupled to the holder 100 on a main PCB 300 of a mobile phone, and then performs an SMD reflow process. Because the mobile phone manufacturer does not need to assemble the SMD condenser microphone 200 and the microphone holder 100, assembly processes and manufacturing time and costs are reduced compared to the related art. Also, because the coupling of the microphone 200 and holder 100 according to the present invention may be overseen and performed with precision by a professional in a microphone manufacturing company, a reduction in the sound qualities of the microphone during assembly can be prevented.

The method of mounting the SMD microphone holder 100 described above with reference to FIGS. 3 through 8 involves the use of a high heat resistant material for the holder that can withstand temperatures in a reflow process, in order to form the holder 100 with a cap body 110 and cylindrical portion 120 defining the cavity 130 in which the microphone 200 is mounted.

Also, in the mounting method according to the present invention, the microphone 200 mounted on the mainboard 300, as shown in FIG. 12, is mounted on top of the mainboard 300 through an SMD method, is protected by the SMD microphone holder 100, and is supported by the mobile phone cover 310 above the SMD microphone holder 100, thus forming a mic mounting structure of the mobile phone.

While the present invention has been described and illustrated herein with reference to a cylindrical holder for mounting a cylindrical microphone in preferred embodiments, a hexahedral or other shape may be equally applied in the mounting of the microphone.

As described above, in the SMD reflow process of the SMD microphone holder according to the present invention, infiltration of flux and other impurities into the sound holes of the microphone can be prevented, and deterioration of the sound qualities of the microphone can also be prevented during an SMD reflow process, for a high industrial applicability.

Also, because a mobile phone manufacturer does not have to assemble the SMD condenser microphone with the microphone holder (as is the case in the related art), the assembly process is shortened, as are manufacturing time and cost. Furthermore, because the coupling of the microphone and the holder is performed at the microphone manufacturer, according to the present invention, deterioration of the microphone's sound qualities during assembly can be prevented.

While the present invention has been described and illustrated herein with reference to preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

1. An SMD (surface mounted device) microphone holder capable of having an SMD microphone mounted within, the SMD microphone holder comprising:
a cap body formed of a heat resistant material capable of withstanding a reflow temperature, and defining a cavity for mounting the SMD microphone therein; and
an annular cylindrical portion integrally formed with the cap body and formed of a heat resistant material capable of withstanding a reflow temperature.

2. The SMD microphone holder of claim 1, wherein the cap body comprises:
a center hole formed in a center of an upper surface of the cap body, through which sound from outside enters;
a tool contacting surface formed around the center hole, for facilitating use of a vacuum tool during a mounting of the SMD microphone; and
a shock absorbing protrusion formed on an upper, inner perimeter surface of the cap body in a radial direction about the center hole, the shock absorbing protrusion for averting direct surface friction between the cap body and a sound hole of the SMD microphone when the vacuum tool is used.

3. The SMD microphone holder of claim 2, wherein the cap body further comprises:
an outer surface having a conical taper; and
a hole perimeter formed to protrude upward from around the center hole and having a sloped surface.

4. The SMD microphone holder of claim 1, wherein the cylindrical portion has an inner diameter that is formed approximately a predetermined φ (phi) smaller than an outer diameter of the SMD microphone, for preventing disengaging of the SMD microphone after the SMD microphone is mounted.

5. The SMD microphone holder of claim 1, wherein the heat resistant material is selected from the group including soft high heat resistant silicon, soft high heat resistant rubber, and high heat resistant plastic.

6. A method for mounting an SMD (surface mounted device) microphone, comprising:
preparing an SMD condenser microphone;
preparing an SMD microphone holder;
coupling the SMD condenser microphone with the SMD microphone holder;
positioning the coupled SMD condenser microphone and the SMD microphone holder on a mainboard of an electronic device; and
performing a reflow process on the mainboard with the coupled SMD condenser microphone and the SMD microphone holder positioned thereon.

7. The SMD microphone holder of claim 2, wherein the heat resistant material is selected from the group including soft high heat resistant silicon, soft high heat resistant rubber, and high heat resistant plastic.

8. The SMD microphone holder of claim 3, wherein the heat resistant material is selected from the group including soft high heat resistant silicon, soft high heat resistant rubber, and high heat resistant plastic.

9. The SMD microphone holder of claim 4, wherein the heat resistant material is selected from the group including soft high heat resistant silicon, soft high heat resistant rubber, and high heat resistant plastic.
